(19) United States
(12) Patent Application Publication
(10) Pub. No.: US 2026/0197967 A1
(43) Pub. Date: Jul. 9, 2026

(54) COOLING HOSE TRANSLATION SYSTEM FOR AN INFORMATION HANDLING SYSTEM

(71) Applicant: Dell Products L.P., Round Rock, TX (US)

(72) Inventor: Eduardo Escamilla, Round Rock, TX (US)

(21) Appl. No.: 19/011,700

(22) Filed: Jan. 7, 2025

(51) Int. Cl. H05K 7/20; G06F 1/20

(52) U.S. Cl. CPC H05K 7/20254; G06F 1/20; H05K 7/20272; G06F 2200/201

(57) ABSTRACT

An information handling system, including a cold plate assembly, including: a cold plate bracket including a slot having a first end and a second end positioned opposite to the first end; and cooling hoses; connection elements coupled to a processing element of a printed circuit board (PCB); a translation assembly coupled to the cold plate bracket, including: an arm coupled to the cold plate bracket at a pivot point at a first end of the arm, the arm including: a stop pin positioned within the slot of the cold plate bracket; a position pin; a holder bracket coupled to the arm at a second end of the arm opposite to the first end, the holder bracket configured to hold at least a portion of the cooling hoses; a flexible tab coupled to the cold plate bracket, the flexible tab including a first hole and a second hole.

### BACKGROUND

### Field of the Disclosure

The disclosure relates generally to an information handling system, and in particular, a cooling hose translation system for an information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Liquid cooling systems in information handling systems use a liquid coolant, typically a mixture of water and additives, to absorb and transfer heat away from critical components like the CPU and GPU. The coolant is pumped through a series of tubes and blocks that are attached to these components, where it absorbs the heat generated during operation. This heated coolant is then circulated to a radiator, where fans help dissipate the heat into the surrounding air. By efficiently managing heat, liquid cooling systems help maintain lower temperatures, which can improve performance and extend the lifespan of the computer's components.

### SUMMARY

Innovative aspects of the subject matter described in this specification may be embodied in an information handling system, including a printed circuit board (PCB); a cold plate assembly coupled to the PCB, including: a cold plate bracket including a slot having a first end and a second end positioned opposite to the first end; and cooling hoses; a processing component coupled to the PCB; connection elements coupled to the PCB and coupled to the processing component, the connection elements positioned between the cooling hoses and the PCB; a translation assembly coupled to the cold plate bracket, including: an arm coupled to the cold plate bracket at a pivot point at a first end of the arm, the arm including: a lift tab positioned at a second end of the arm opposite to the first end of the arm; a stop pin positioned within the slot of the cold plate bracket; a position pin; a holder bracket coupled to the arm at a second end of the arm opposite to the first end, the holder bracket configured to hold at least a portion of the cooling hoses; a flexible tab coupled to the cold plate bracket, the flexible tab including a first hole and a second hole; wherein, when the translation assembly is in a first state: the stop pin is at the first end of the slot of the cold plate bracket, the position pin is positioned within the first hole of the flexible tab, and the arm is in a stowed position relative to the cold plate bracket such that the cooling hoses are proximate to the connection elements; wherein, when the translation assembly is in a second state: the stop pin is at a second end of the slot of the cold plate bracket, the position pin is positioned within the second hole of the flexible tab, and the arm is in an angled position relative to the cold plate bracket such that the cooling hoses are spaced-apart from the connection elements to define a gap therebetween.

Other embodiments of these aspects include corresponding systems and apparatus.

These and other embodiments may each optionally include one or more of the following features. For instance, the flexible tab is configured to apply a spring pressure to the arm to maintain the arm proximate to the cold plate bracket.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of the information handling system for including a translation assembly.

FIG. 3 illustrates the translation assembly in a first state.

FIG. 4 illustrates a perspective view of the translation assembly.

FIG. 5 illustrates a back view of the translation assembly.

FIG. 6 illustrates the translation assembly in a second state.

### DESCRIPTION OF PARTICULAR EMBODIMENT(S)

This disclosure discusses a translation assembly for an information handling system, including an arm coupled to a cold plate bracket of the information handling system at a pivot point at a first end of the arm, the arm including: a stop pin positioned within a slot of the cold plate bracket; a position pin; a holder bracket coupled to the arm at a second end of the arm opposite to the first end, the holder bracket configured to hold at least a portion of cooling hoses of the information handling system; a flexible tab coupled to the cold plate bracket, the flexible tab including a first hole and a second hole; wherein, when the translation assembly is in a second state, the stop pin is at a second end of the slot of the cold plate bracket, the position pin is positioned within the second hole of the flexible tab, and the arm is in an angled positioned relative to the cold plate bracket such that the cooling hoses are spaced-apart from the connection elements to define a gap therebetween.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

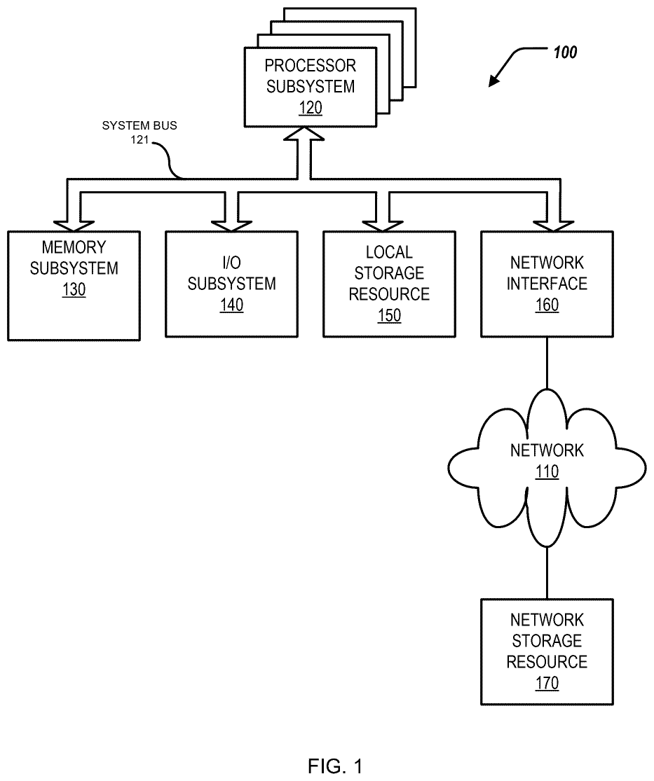

Particular embodiments are best understood by reference to FIGS. 1-6 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

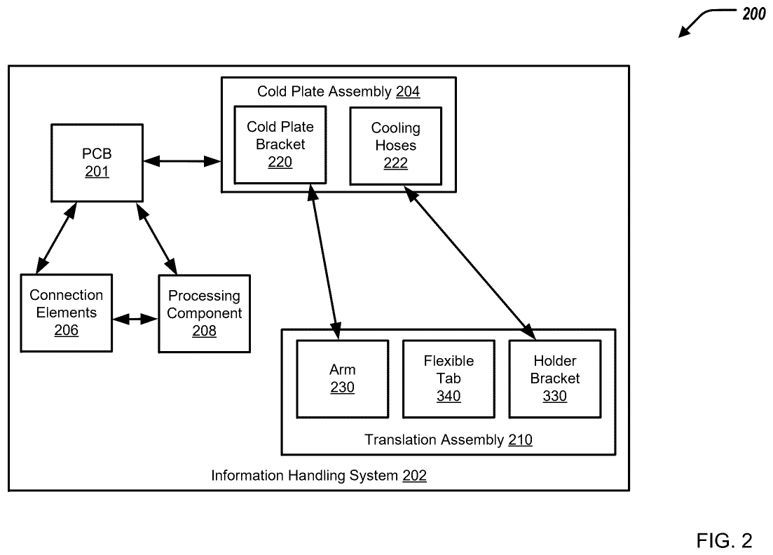

Turning to FIG. 2, FIG. 2 illustrates an environment 200 including an information handling system 202. The information handling system 202 can include printed circuit board (PCB) 201, a cold plate assembly 204, connection elements 206, a processing component 208, and a translation assembly 210. In some examples, the information handling system 202 is similar to, or includes, the information handling system 100 of FIG. 1.

The cold plate assembly 204 can include a cold plate bracket 220 and cooling hoses 222. The translation assembly 210 can include an arm 230, a flexible tab 340, and a holder bracket 330.

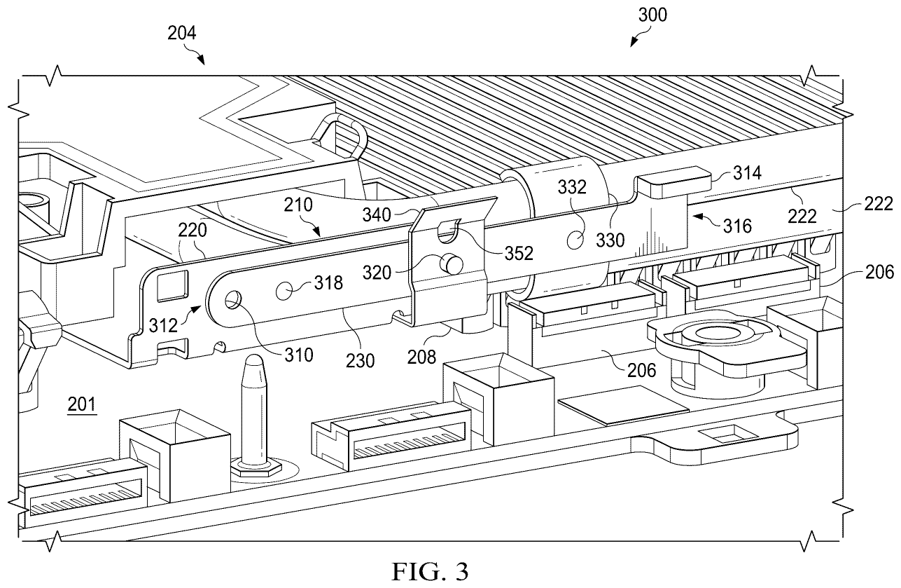

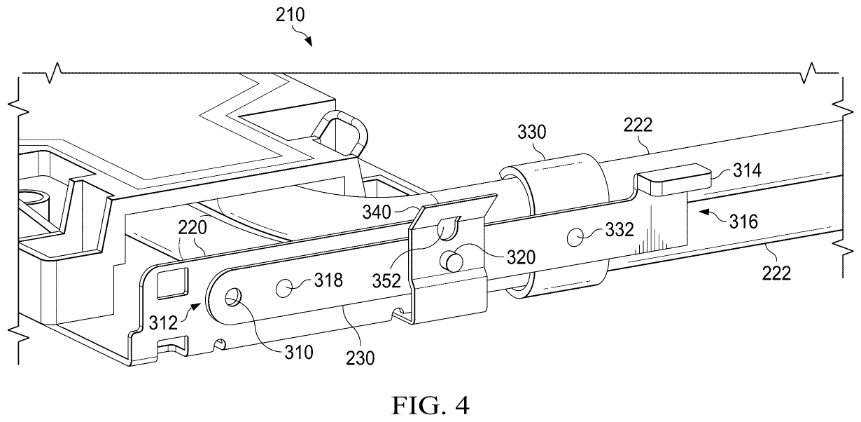

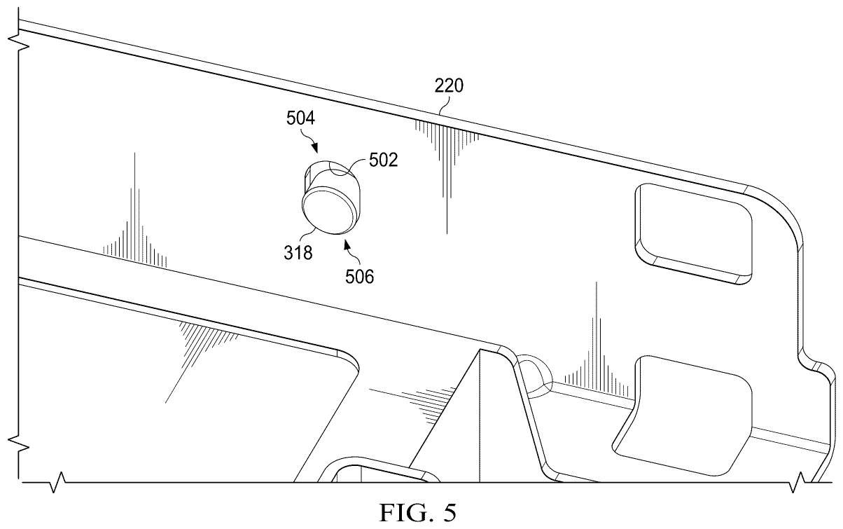

FIG. 3 illustrates an environment 300 including the information handling system 202, and in particular, a perspective view of the translation assembly 210. FIG. 4 illustrates a perspective view of the translation assembly 210. Referring to FIGS. 3 and 4, the information handling system 202 can include the PCB 201 and the cold plate assembly 204. The cold plate assembly 204 can be coupled to the PCB 201. The cold plate assembly 204 can include the cold plate bracket 220. FIG. 5 illustrates a back of the cold plate bracket 220. Referring to FIGS. 3-5, the cold plate bracket 220 can include a slot 502. The slot 502 can include a first end 504 and a send end 506 positioned opposite to the first end 504.

Referring back to FIGS. 3 and 4, the information handling system 202 can further include the cooling hoses 222. The information handling system 202 can include any number of cooling hoses 226 222 depending on the application desired. The information handling system 202 can include processing component 208. The processing component 208 can be any processing component employed at the information handling system 202, such as a central processing unit (CPU) or graphical processing unit (GPU). The processing component 208 can be coupled to the PCB 201. The information handling system 202 can include connection elements 206. The connection elements 206 can include high-speed input/output (HSIO) connectors. The connection elements 206 can be physically located proximate to the processing component 208 for signal integrity optimization. The connection elements 206 are coupled to the PCB 201 and coupled to the processing component 208. The connection elements 206 provide an interface to the processing component 208. That is, cables (not shown) can be connected to the connection elements 206 such that communication with the processing components 208 is enabled. The processing components 208 can transfer data over the cables (not shown) via the interface the connection elements 206 provides. Moreover, the connection elements 206 are positioned between the cooling hoses 222 and the PCB 201.

The translation assembly 210 is coupled to the cold plate bracket 220. The translation assembly 210 includes the arm 230. The arm 230 is coupled to the cold plate bracket 220 at a pivot point 310. The pivot point 310 is at a first end 312 of the arm 230. The arm 230 includes a lift tab 314 positioned at a second end 316 of the arm 230. The arm 230 further includes a stop pin 318 (the back of the stop pin 318 is shown in FIG. 5 without the arm 230 being illustrated). The stop pin 318 of the arm 230 is positioned within the slot 502 of the cold plate bracket 220. The stop pin 318 limits the travel of the arm 230, described further herein. The arm 230 further includes a position pin 320.

The translation assembly 210 further includes a holder bracket 330. The holder bracket 330 is coupled to the arm 230 at the second end 316 of the arm 230. The holder bracket 330 is coupled to the arm 230 via a bracket pin 332. The holder bracket 330 holds the hoses 222, or a portion of the hoses 222. Specifically, the holder bracket 330 is mounted via the bracket pin 332 to allow/facilitate rotation about the bracket pin 332, and pivot about the bracket pin 332. This allows/facilitates movement of the hoses 222, described further herein.

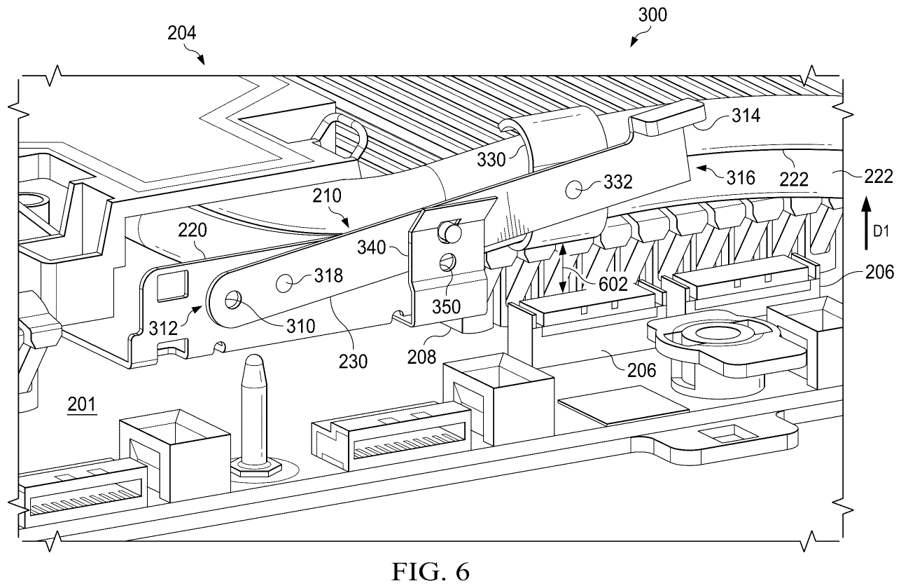

The translation assembly 210 further includes a flexible tab 340. The flexible tab 340 is coupled to the cold plate bracket 220. The flexible tab 340 includes a first hole 350 (shown more clearly in FIG. 6) and a second hole 352. The flexible tab 340 is able to lock the arm 230 in one of the two positions defined by the first hole 350 or the second hole 352. Further, the flexible tab 340 applies a spring pressure to the arm 230 to maintain the arm proximate to the cold plate bracket 220.

To that end, as mentioned herein, the connection elements 206 are physically located proximate to the processing component 208 for signal integrity optimization. However, in doing so, the connection elements 206 are positioned between the cooling hoses 222 and the PCB 201. To access the connection elements 206 (as they are positioned “underneath” the cooling hoses 222), the cooling hoses 222 are to be moved to provide access to the connection elements 206. The translation assembly 210 facilitates translation of the cooling hoses 222 to “temporarily” lift the cooling hoses 222 to create access space to the connection elements 206, described further herein.

Referring to FIG. 3, the translation assembly 210 is shown in a first state. When the translation assembly 210 is in the first state, the arm 230 is in a stowed position relative to the cold plate bracket 220 such that the cooling hoses 222 are proximate to the connection elements 206. Specifically, when the translation assembly 210 is in the first state, the stop pin 318 is at the first end 504 of the slot 502 of the cold plate bracket 220 (slot 502 shown in FIG. 5). Further, when the translation assembly 210 is in the first state, the position pin 320 is positioned within the first hole 350 of the flexible tab 340 (first hole 350 shown in FIG. 6). Thus, when the translation assembly 210 is in the first state, the arm 230 is in a stowed position - that is, the arm 230 is in a substantially parallel orientation with respect to the cold plate bracket 220.

Referring to FIG. 6, the translation assembly 210 is shown in a second state. When the translation assembly 210 is in the second state, the arm 230 is in an angled position relative to the cold plate bracket 220 such that the cooling hoses 222 are spaced-apart from the connection elements 206 to define a gap 602 therebetween. Specifically, the translation assembly 210 is rotated from the first state (shown in FIG. 3) to the second state (shown in FIG. 6). In some examples, a user (not shown) disengages the position pin 320 from being positioned within the first hole 350. Specifically, the user can apply directional force to the flexible tab 340 (opposite to the spring pressure the flexible tab 340 applies to the arm 230) to disengage the position pin 320 from being positioned within the first hole 350. Concurrently, the user can grasp/hold the lift tab 314 and apply rotational force to rotate the arm 230 about the pivot point 310. The arm 230 rotates about the pivot point 310 until the stop pin 318 is positioned at the second end 506 (shown in FIG. 5) of the slot 502 of the cold plate bracket 220. When the stop pin 318 is positioned at the second end 506 of the slot 502 of the cold plate bracket 220, the position pin 320 engages with the second hole 352 (shown in FIG. 4) of the flexible tab 340 such that the position pin 320 is positioned within the second hole 352 to maintain the positioning of the arm 230 in the second state. The user can then release their grasp/hold of the lift tab 314 and/or the flexible tab 340. Thus, when the translation assembly 210 is in the second state, the arm 230 is in an angled position - that is, the arm 230 is in an angled orientation with respect to the cold plate bracket 220.

Moreover, during such rotational movement of the arm 230 from the first state to the second state, the holder bracket 330 translates the hoses 222 in a direction D1 proximate to where the holder bracket 330 holds the hoses 222. Further, the holder bracket 330 rotates about the bracket pin 332 to minimize or prevent undue strain on the hoses 222 when the arm 230 goes from the first state to the second state.

Furthermore, the translation assembly 210 can transition from the second state (shown in FIG. 6) to the first state (shown in FIG. 3). Specifically, in some examples, the user (not shown) disengages the position pin 320 from being positioned within the second hole 352. Specifically, the user can apply directional force to the flexible tab 340 (opposite to the spring pressure the flexible tab 340 applies to the arm 230) to disengage the position pin 320 from being positioned within the second hole 352. Concurrently, the user can grasp/hold the lift tab 314 and apply rotational force to rotate the arm 230 about the pivot point 310. The arm 230 rotates about the pivot point 310 until the stop pin 318 is positioned at the first end 504 (shown in FIG. 5) of the slot 502 of the cold plate bracket 220. When the stop pin 318 is positioned at the first end 504 of the slot 502 of the cold plate bracket 220, the position pin 320 engages with the first hole 350 (shown in FIG. 6) of the flexible tab 340 such that the position pin 320 is positioned within the first hole 350 to maintain the positioning of the arm 230 in the first state. The user can then release their grasp/hold of the lift tab 314 and/or the flexible tab 340. Thus, when the translation assembly 210 is in the first state, the arm 230 is in a stowed position - that is, the arm 230 is in a substantially parallel orientation with respect to the cold plate bracket 220.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. An information handling system, comprising:
a cold plate assembly, including:
a cold plate bracket including a slot having a first end and a second end positioned opposite to the first end; and
cooling hoses;
connection elements coupled to a processing element of a printed circuit board (PCB);
a translation assembly coupled to the cold plate bracket, including:
an arm coupled to the cold plate bracket at a pivot point at a first end of the arm, the arm including:
a stop pin positioned within the slot of the cold plate bracket;
a position pin;
a holder bracket coupled to the arm at a second end of the arm opposite to the first end, the holder bracket configured to hold at least a portion of the cooling hoses;
a flexible tab coupled to the cold plate bracket, the flexible tab including a first hole and a second hole;
wherein, when the translation assembly is in a second state:
the stop pin is at a second end of the slot of the cold plate bracket,
the position pin is positioned within the second hole of the flexible tab, and
the arm is in an angled positioned relative to the cold plate bracket such that the cooling hoses are spaced-apart from the connection elements to define a gap therebetween.

2. The information handling system of claim 1, wherein, when the translation assembly is in a first state:
the stop pin is at the first end of the slot of the cold plate bracket,
the position pin is positioned within the first hole of the flexible tab, and
the arm is in a stowed position relative to the cold plate bracket such that the cooling hoses are proximate to the connection elements.

3. The information handling system of claim 2, further comprising:
the printed circuit board (PCB),
wherein the cold plate assembly is coupled to the PCB,
wherein the connection elements are coupled to the PCB.

4. The information handling system of claim 3, further comprising:
the processing element coupled to the PCB,
wherein the connection elements are positioned between the cooling hoses and the PCB.

5. The information handling system of claim 4, wherein the translation assembly further includes a lift tab positioned at a second end of the arm opposite to the first end.

6. The information handling system of claim 1, wherein the flexible tab is configured to apply a spring pressure to the arm to maintain the arm proximate to the cold plate bracket.

7. A translation assembly for an information handling system, comprising:
an arm coupled to a cold plate bracket of the information handling system at a pivot point at a first end of the arm, the arm including:
a stop pin positioned within a slot of the cold plate bracket;
a position pin;
a holder bracket coupled to the arm at a second end of the arm opposite to the first end, the holder bracket configured to hold at least a portion of cooling hoses of the information handling system;
a flexible tab coupled to the cold plate bracket, the flexible tab including a first hole and a second hole;
wherein, when the translation assembly is in a second state:
the stop pin is at a second end of the slot of the cold plate bracket,
the position pin is positioned within the second hole of the flexible tab, and
the arm is in an angled position relative to the cold plate bracket such that the cooling hoses are spaced-apart from the connection elements to define a gap therebetween.

8. The translation assembly of claim 7, wherein, when the translation assembly is in a first state:
the stop pin is at a first end of the slot of the cold plate bracket, the first end opposite to the second end of the cold plate bracket,
the position pin is positioned within the first hole of the flexible tab, and
the arm is in a stowed position relative to the cold plate bracket such that the cooling hoses are proximate to connection elements of the information handling system.

9. The information handling system of claim 7, wherein the translation assembly further includes a lift tab positioned at the second end of the arm.

10. An information handling system, comprising:
a printed circuit board (PCB);
a cold plate assembly coupled to the PCB, including:
a cold plate bracket including a slot having a first end and a second end positioned opposite to the first end; and
cooling hoses;
a processing component coupled to the PCB;
connection elements coupled to the PCB and coupled to the processing component, the connection elements positioned between the cooling hoses and the PCB;
a translation assembly coupled to the cold plate bracket, including:
an arm coupled to the cold plate bracket at a pivot point at a first end of the arm, the arm including:
a lift tab positioned at a second end of the arm opposite to the first end of the arm;
a stop pin positioned within the slot of the cold plate bracket;
a position pin;
a holder bracket coupled to the arm at a second end of the arm opposite to the first end, the holder bracket configured to hold at least a portion of the cooling hoses;
a flexible tab coupled to the cold plate bracket, the flexible tab including a first hole and a second hole;
wherein, when the translation assembly is in a first state:
the stop pin is at the first end of the slot of the cold plate bracket,
the position pin is positioned within the first hole of the flexible tab, and
the arm is in a stowed position relative to the cold plate bracket such that the cooling hoses are proximate to the connection elements;
wherein, when the translation assembly is in a second state:
the stop pin is at a second end of the slot of the cold plate bracket,
the position pin is positioned within the second hole of the flexible tab, and
the arm is in an angled position relative to the cold plate bracket such that the cooling hoses are spaced-apart from the connection elements to define a gap therebetween.

11. The information handling system of claim 10, wherein the flexible tab is configured to apply a spring pressure to the arm to maintain the arm proximate to the cold plate bracket.
